(19) United States
(12) Patent Application Publication
(10) Pub. No.: US 2025/0054754 A1
(43) Pub. Date: Feb. 13, 2025

(54) PRODUCTION METHOD FOR NITRIDE CRYSTAL SUBSTRATE, AND PEELED INTERMEDIATE

(71) Applicant: SUMITOMO CHEMICAL COMPANY, LIMITED, Tokyo (JP)

(72) Inventors: Masafumi YOKOYAMA, Hitachi-shi (JP); Hajime FUJIKURA, Hitachi-shi (JP); Taichiro KONNO, Hitachi-shi (JP)

(73) Assignee: SUMITOMO CHEMICAL COMPANY, LIMITED, Tokyo (JP)

(21) Appl. No.: 18/794,616

(22) Filed: Aug. 5, 2024

(30) Foreign Application Priority Data
Aug. 7, 2023 (JP) 2023-128764

(51) Int. Cl. H01L 21/02; C25F 3/12; C30B 25/18; C30B 29/40

(52) U.S. Cl. CPC H01L 21/0254; C25F 3/12; C30B 25/183; C30B 25/186; C30B 29/406; H01L 21/02389; H01L 21/02458

(57) ABSTRACT

To stably grow a regrowth layer. A production method for a nitride crystal substrate includes: (a) preparing a base substrate; (b) forming an intermediate layer including n-type group III nitride crystal, above the base substrate; (c) forming a cover layer on the intermediate layer, the cover layer including group III nitride crystal having a carrier concentration lower than a carrier concentration of the intermediate layer; (d) making the intermediate layer porous through dislocations in the cover layer by performing an electrochemical process, while maintaining a surface condition of the cover layer; (e) epitaxially growing a regrowth layer comprising group III nitride crystal, on the cover layer; and (f) peeling off the regrowth layer from the base substrate by using at least a portion of the intermediate layer made porous as a boundary.

### FIELD AND BACKGROUND OF TIE INVENTION

The present disclosure relates to a production method for a nitride crystal substrate and a peeled intermediate.

Various production methods for obtaining nitride crystal substrates comprising group III nitride crystal have been disclosed (see, for example, Japanese Patent Laid Open Publication No. 2003-178984).

### SUMMARY OF THE INVENTION

The present disclosure has an object to stably grow a regrowth layer.

According to an aspect of the present disclosure, there is provided a production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process, while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary,
(e) comprising:
(e1) growing a first regrowth layer on the cover layer at a first growth temperature; and
(e2) growing a second regrowth layer on the first regrowth layer at a second growth temperature, wherein
in (e1),
the first growth temperature is set lower than the second growth temperature.

According to another aspect of the present disclosure, there is provided a peeled intermediate obtained by the above production method for a nitride crystal substrate, the peeled intermediate comprising:
at least the cover layer and the regrowth layer.

According to the present disclosure, the regrowth layer can be grown stably.

### BRIEF DESCRIPTION OF THE DRAWINGS

FIG. 1 is a flowchart showing a production method for a nitride crystal substrate according to one embodiment of the present disclosure.

FIG. 2A is a schematic cross-sectional view showing the production method for a nitride crystal substrate according to the embodiment of the present disclosure.

FIG. 2B is a schematic cross-sectional view showing the production method for a nitride crystal substrate according to the embodiment of the present disclosure.

FIG. 3A is a schematic cross-sectional view showing the production method for a nitride crystal substrate according to the embodiment of the present disclosure.

FIG. 3B is a schematic cross-sectional view showing the production method for a nitride crystal substrate according to the embodiment of the present disclosure.

FIG. 4 is a schematic cross-sectional view showing the production method for a nitride crystal substrate according to the embodiment of the present disclosure.

FIG. 5 is a diagram showing changes in the temperature in a regrowth step according to the embodiment of the present disclosure.

FIG. 6 is a schematic cross-sectional view showing the production method for a nitride crystal substrate according to the embodiment of the present disclosure.

FIG. 7 is a schematic cross-sectional view showing the production method for a nitride crystal substrate according to the embodiment of the present disclosure.

FIG. 8 is a schematic cross-sectional view showing the production method for a nitride crystal substrate according to the embodiment of the present disclosure.

FIG. 9 is a schematic cross-sectional view showing the production method for a nitride crystal substrate according to the embodiment of the present disclosure.

FIG. 10 is a diagram showing changes in the temperature in a regrowth step according to Modification Example 1.

FIG. 11 is a diagram showing changes in the temperature in a regrowth step of Comparative Example.

FIG. 12 is a schematic cross-sectional view showing the state of Comparative Example when the temperature is increased to a regrowth temperature.

FIG. 13 is a micrograph of a surface of a seed substrate heated to 883° C. in Experiment 1, as observed with an optical microscope.

FIG. 14 is a micrograph of a surface of the seed substrate heated to 963° C. in Experiment 1, as observed with the optical microscope.

FIG. 15 is a micrograph of a surface of the seed substrate heated to 1033° C. in Experiment 1, as observed with the optical microscope.

FIG. 16 is a micrograph of a surface of a regrowth layer peeled off in Sample A1 of Experiment 2, as observed with the optical microscope.

FIG. 17 is a micrograph of a surface of a regrowth layer peeled off in Sample C4 in Experiment 2, as observed with the optical microscope.

### DETAILED DESCRIPTION

### <Findings Obtained by Inventors>

The inventors have studied the following method as a production method for a nitride crystal substrate. First, an intermediate layer and a cover layer, each containing group III nitride crystal, are grown on a base substrate in this order, and an electrochemical process is performed on this laminated body. In this way, a seed substrate with the intermediate layer made porous is fabricated. Next, by using this seed substrate, a thick group III nitride crystal layer is regrown on the seed substrate. The group III nitride crystal layer is then sliced to obtain a nitride crystal substrate. In this study, the inventors have made the following findings.

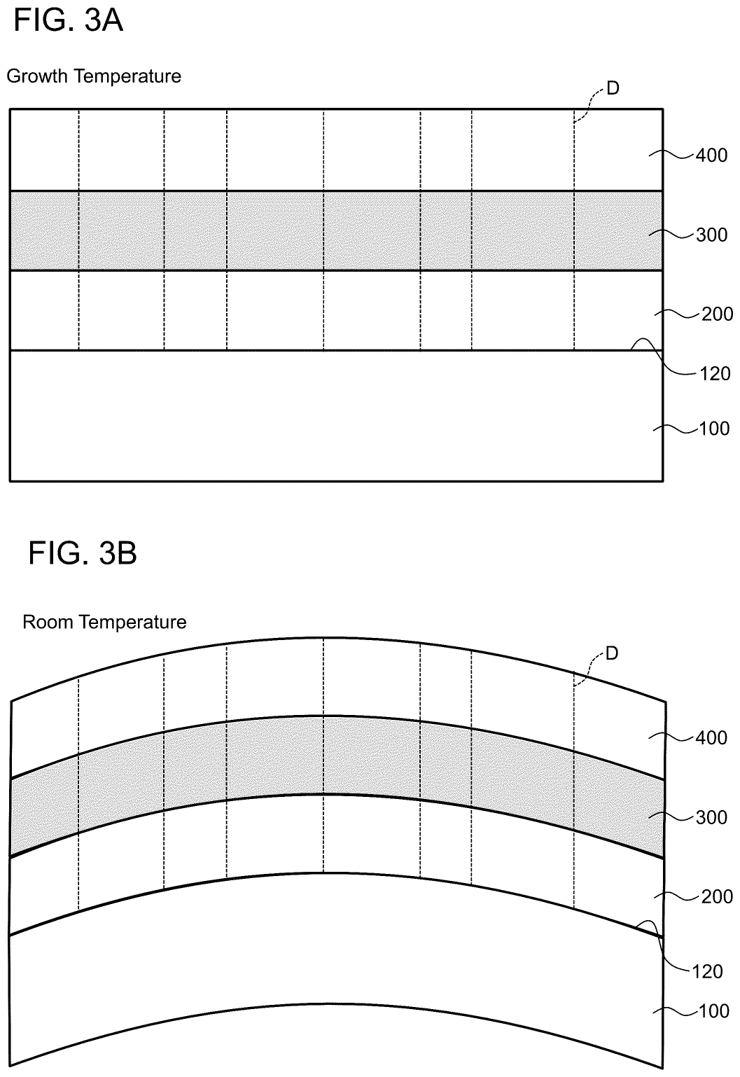

After a cover layer growth step, when the temperature is decreased from the growth temperature to room temperature, the entire laminated body is warped such that a surface of the cover layer becomes convex due to a difference in linear expansion coefficient between the base substrate and the intermediate layer and cover layer (in a condition corresponding to FIG. 3B described later).

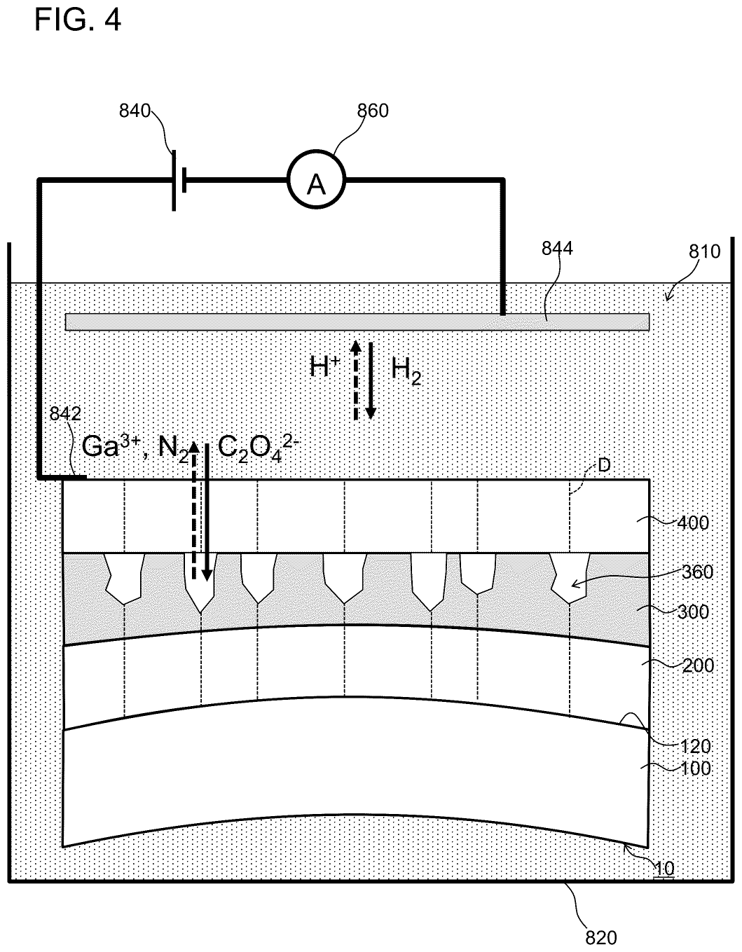

In this condition, when a porous step is performed through the electrochemical process, the cover layer and the base substrate are separated from each other, while the intermediate layer made porous is interposed therebetween. Thus, the seed substrate is brought into a condition closer to a configuration where the layer on the base substrate is thin. As a result, the cover layer is brought into a condition of being nearly flat, thus reducing the warpage of the base substrate (in a condition corresponding to that shown in FIG. 4 described later).

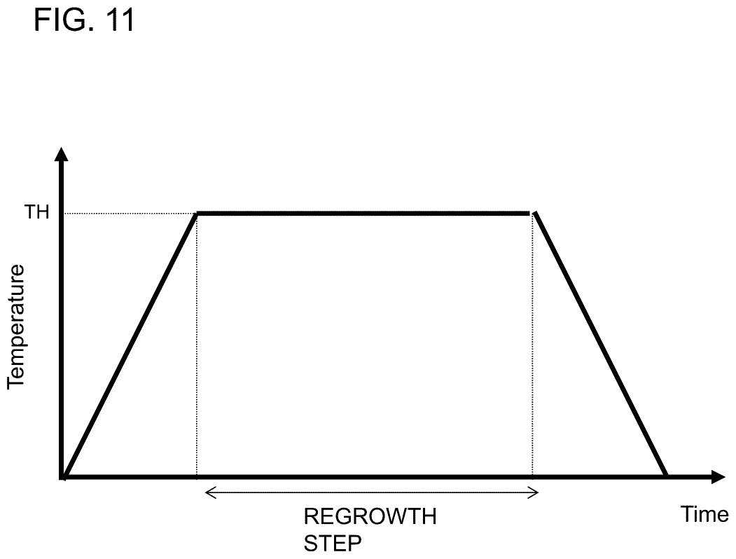

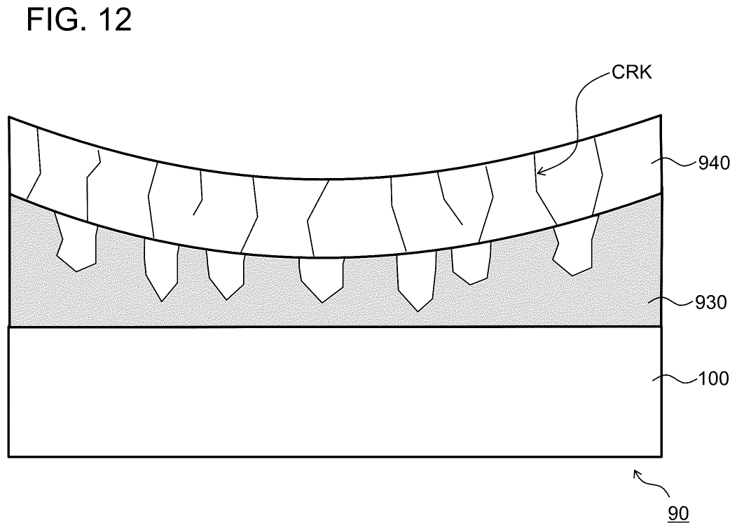

Next, when the temperature is increased directly to a growth temperature TH of group III nitride crystal in the regrowth step as shown in FIG. 11, a base substrate 100 extends and returns to being flat as the temperature thereof increases, whereas a cover layer 940 is warped such that the surface of the cover layer 940 on a porous intermediate layer 930 is recessed, as shown in FIG. 12. Consequently, cracks CRK occur in the cover layer 940.

When the regrowth layer is grown thickly with the cracks CRK occurring in the cover layer 940, at least any one of a crack and a pit may occur in the regrowth layer.

As a result of their diligent studies, the inventors have succeeded in stably growing the regrowth layer by adjusting the growth temperature in two stages during the regrowth step.

The present disclosure below is based on the above findings obtained by the inventors.

### DETAILS OF EMBODIMENT OF PRESENT DISCLOSURE

Next, one embodiment of the present disclosure will be described with reference to the accompanying drawings. The present disclosure is not limited to these examples, but is indicated by the claims and intended to include all changes within the meaning and scope of the claims and equivalents thereof.

### One Embodiment of Present Disclosure

One embodiment of the present disclosure will be described below with reference to the drawings.

### (1) Production Method for Nitride Crystal Substrate

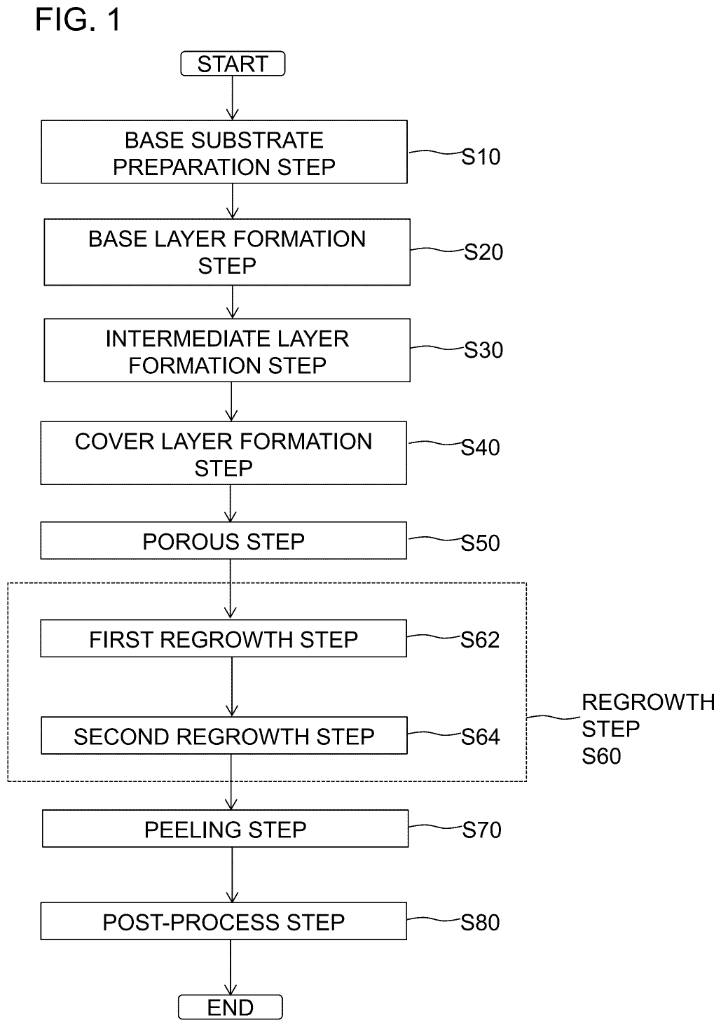

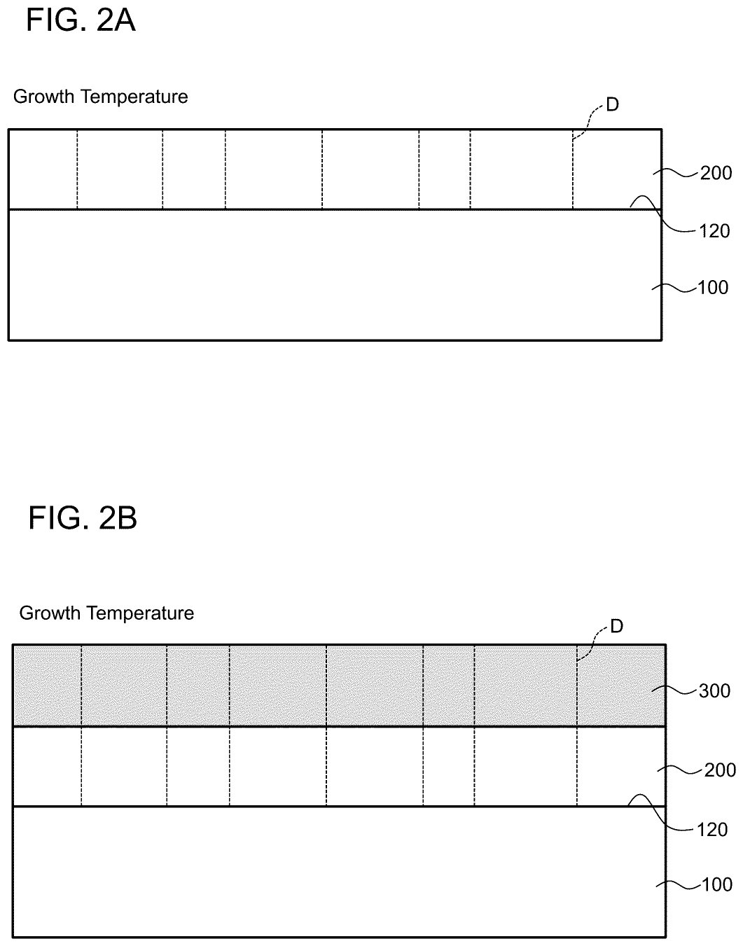

Referring to FIGS. 1 to 9, the production method for a nitride crystal substrate according to the present embodiment is described. In FIGS. 2A to 4 and 6 to 9, hatching of the cross sections except for an intermediate layer 300 is omitted.

In the following, in group III nitride crystal with a wurtzite structure, a <0001> axis (e.g., [0001] axis) is referred to as a “c-axis”, and (0001) as a “c-plane”. The (0001) is sometimes referred to as a “+c-plane (group III element polar plane)”, and (000-1) as the “−c-plane (nitrogen (N) polar plane)”. The term “carrier concentration” in the present disclosure means a free carrier concentration at room temperature (22° C.).

As shown in FIG. 1, the production method for a nitride crystal substrate according to the present embodiment includes, for example, a base substrate preparation step S10, a base layer formation step S20, an intermediate layer formation step S30, a cover layer formation step S40, a porous step S50, a regrowth step S60, a peeling step S70, and a post-process step S80.

### (S10: Base Substrate Preparation Step)

First, as shown in FIG. 2A, the base substrate 100 is prepared.

In the present embodiment, the base substrate 100 comprising, for example, a material different from group III nitride is prepared. Specifically, the base substrate 100 is, for example, a sapphire substrate, a silicon carbide (SiC) substrate, a silicon (Si) substrate, or a gallium arsenide (GaAs) substrate. The base substrate 100 may be insulating or conductive. Here, the base substrate 100 is, for example, a sapphire substrate.

The diameter of the base substrate 100 is, for example, 2 inches (50 mm) or more or may be 4 inches (100 mm) or more. This allows for the growth of a regrowth layer 500 with a large area, described later.

The base substrate 100 has a thickness of, for example, 150 μm or more and 3 mm or less.

The base substrate 100 has a main surface 120, which becomes the growth surface, for example. In a case where the base substrate 100 is a sapphire substrate or SiC substrate, a crystal plane with a low index closest to that of the main surface 120 is, for example, the c-plane (+c-plane). In a case where the base substrate 100 is a Si substrate or GaAs substrate, a crystal plane with the low index closest to that of the main surface 120 is, for example, (001) or (111).

In the present embodiment, the c-plane of the base substrate 100 may be inclined with respect to the main surface 120. That is, the c-axis of the base substrate 100 may be inclined at a predetermined off-angle with respect to the normal of the main surface 120. The off-angle of the base substrate 100 is, for example, 0° or more and 5° or less.

The main surface 120 of the base substrate 100 has an arithmetic mean roughness (Ra) of, for example, less than 0.3 nm.

### (S20: Base Layer Formation Step)

After preparing the base substrate 100, a base layer 200 including group III nitride crystal is formed (the base layer 200 comprising group III nitride crystal is formed) on the base substrate 100, for example, by a vapor phase growth method, as shown in FIG. 2A.

Specifically, an aluminum nitride (AlN) buffer layer is grown by supplying aluminum chloride (AlCl₃) gas and ammonia (NH₃) gas to the base substrate 100 heated to a predetermined growth temperature, for example, using a hydride vapor phase epitaxy (HVPE) method. Next, a gallium nitride (GaN) layer is grown by supplying gallium chloride (GaCl) gas and NH₃ gas to the base substrate 100 heated to the predetermined growth temperature. The growth temperature of each layer is, for example, 900° C. or higher and 1100° C. or lower. In the way above, the AlN buffer layer and the GaN layer are formed as the base layer 200 on the main surface 120 of the base substrate 100 in this order. However, the base layer 200 may not have an AlN buffer layer.

In the present embodiment, the base layer 200 is of, for example, n-type. Specifically, when growing the GaN layer as the base layer 200, dichlorosilane (SiH₂Cl₂) gas is further supplied as an n-type dopant gas to grow a Si-doped GaN layer.

In the present embodiment, a carrier concentration in the GaN layer of the base layer 200 is lower than, for example, a carrier concentration in the intermediate layer 300. In other words, an n-type impurity concentration in the GaN layer of the base layer 200 is lower than, for example, an n-type impurity concentration in the intermediate layer 300. Specifically, the carrier concentration (and n-type impurity concentration) in the base layer 200 is, for example, 2×10¹⁸ cm⁻³ or less, or 1×10¹⁸ cm⁻³ or less. Thus, in the porous step S50 of making the intermediate layer 300 porous by performing the electrochemical process as described later, the base layer 200 can function as an etching stopper located on the lower side of the intermediate layer 300.

The lower limit of the carrier concentration in the GaN layer of the base layer 200 is not limited. However, the carrier concentration in the GaN layer of the base layer 200 may be, for example, 1×10¹⁶ cm⁻³ or more. Thus, since the base layer 200 itself has some conductivity, the etching of the intermediate layer 300 can progress toward a lower portion of the intermediate layer 300 through the electrochemical process during the porous step S50 described later.

The thickness of the base layer 200 is not particularly limited. However, the thickness of the base layer 200 may be, for example, more than 0 nm and 5 μm or less. By setting the thickness of the base layer 200 to 5 μm or less, the total thickness of the laminated layers on the base substrate 100 can be adjusted to, for example, 15 μm or less. This can suppress cracking that would be caused by a difference in linear expansion coefficient between respective layers, including the base substrate 100 and the base layer 200.

In the present embodiment, the crystal plane with the low index closest to the surface of the base layer 200 is the c-plane of the GaN layer. By forming a flat surface of the base layer 200 with such crystal plane in advance, the intermediate layer 300 and a cover layer 400, both having good crystallinity, can be grown on the surface of the base layer 200.

### (S30: Intermediate Layer Formation Step)

After the base layer 200 is formed, the intermediate layer 300 including n-type group III nitride crystal is formed on the base layer 200 located above the base substrate 100, for example, by the vapor phase growth method, as shown in FIG. 2B. (In this step, the intermediate layer 300 comprising group III nitride crystal in a state that does not contain any voids is formed.)

Specifically, a Si-doped GaN layer is grown as the intermediate layer 300 on the base layer 200 using, for example, the HVPE method by supplying GaCl gas, NH₃ gas, and SiH₂Cl₂ gas as n-type dopant gas to the base substrate 100 heated to the predetermined growth temperature. The intermediate layer 300 is grown with the +c-plane as the growth surface.

In the present embodiment, the carrier concentration in the intermediate layer 300 is higher than, for example, each of the carrier concentration in the base layer 200 and the carrier concentration in the cover layer 400. In other words, the n-type impurity concentration in the intermediate layer 300 is higher than, for example, each of the n-type impurity concentration in the base layer 200 and the n-type impurity concentration in the cover layer 400. Specifically, the carrier concentration (and n-type impurity concentration) in the intermediate layer 300 is, for example, 3×10¹⁸ cm⁻³ or more, or may be 1×10¹⁹ cm⁻³ or more. Thus, in the porous step S50 described later, the intermediate layer 300 can be selectively made porous.

The upper limit of the carrier concentration in the intermediate layer 300 is not limited. However, the carrier concentration in the intermediate layer 300 may be, for example, 1×10²⁰ cm⁻³ or less, or 5×10¹⁹ cm⁻³ or less. This can suppress the degradation of the crystallinity of the intermediate layer 300.

In the present embodiment, the thickness of the intermediate layer 300 is, for example, more than 100 nm, or may be 500 nm or more, or 1 μm or more. This allows large voids to be formed in the intermediate layer 300 in the porous step S50 described later. Thus, in the regrowth step S60 described later, voids 360 in the intermediate layer 300 can be maintained. As a result, in the peeling step S70 described later, the regrowth layer 500 can be easily and stably peeled off from the base substrate 100 by using, as a boundary, at least a portion of the intermediate layer 300 maintained in a porous state.

The upper limit of the thickness of the intermediate layer 300 is not limited. However, the thickness of the intermediate layer 300 may be 10 μm or less. By setting the thickness of the intermediate layer 300 to 10 μm or less, the total thickness of the laminated layers on the base substrate 100 can be adjusted to 15 μm or less, for example. This can suppress cracking that would be caused by a difference in linear expansion coefficient between respective layers, including the base substrate 100 and the intermediate layer 300.

### (S40: Cover Layer Formation Step)

After forming the intermediate layer 300, the cover layer 400 including group III nitride crystal is formed (the cover layer 400 comprising group III nitride crystal is formed) on the intermediate layer 300, for example, by the vapor phase growth method, as shown in FIG. 3A.

Specifically, a Si-doped GaN layer is grown as the cover layer 400 on the intermediate layer 300, for example, by the HPE method under the same conditions as those in the intermediate layer formation step S30, except that an amount of SiH₂Cl₂ gas supplied as the n-type dopant gas is less than that in the intermediate layer formation step S30. The cover layer 400 is grown with the +c-plane as the growth surface.

In the present embodiment, the carrier concentration in the cover layer 400 is lower than, for example, the carrier concentration in the intermediate layer 300. In other words, the n-type impurity concentration in the cover layer 400 is lower than, for example, the n-type impurity concentration in the intermediate layer 300. Specifically, the carrier concentration (and n-type impurity concentration) in the cover layer 400 is, for example, 1×10¹⁸ cm⁻³ or less. Thus, in the porous step S50 described later, the intermediate layer 300 can be selectively made porous while suppressing etching of the cover layer 400. That is, under a predetermined voltage, the size of the micro voids in the cover layer 400 can be prevented from increasing, whereas the size of the voids 360 in the intermediate layer 300 increases.

The lower limit of the carrier concentration in the cover layer 400 is not limited. However, the carrier concentration in the cover layer 400 may be, for example, 1×10¹⁶ cm⁻³ or more, or 1×10¹⁷ cm⁻³ or more. In this way, since the cover layer 400 itself has conductivity, the intermediate layer 300 can be connected to an anode 842 via the cover layer 400, so that the entire intermediate layer 300 can be equipotential with the anode 842 during the electrochemical process performed in the porous step S50 of making the intermediate layer 300 porous.

Here, in a state where the cover layer formation step S40 is completed, the base layer 200, the intermediate layer 300, and the cover layer 400 have a plurality of dislocations D passing therethrough in the thickness direction, for example. A dislocation density on the surface of the cover layer 400 is, for example, 1×10⁸ cm⁻² or more and 1×10⁹ cm⁻² or less. The dislocations D in the cover layer 400 are used in the porous step S50 below.

In the present embodiment, the thickness of the cover layer 400 is, for example, 10 nm or more and 2 μm or less, or may be 50 nm or more and 1.5 μm or less.

By setting the thickness of the cover layer 400 to 10 nm or more or 50 nm or more, the cover layer 400 can discharge gas generated by outgassing toward the outside of the cover layer 400 through the dislocations D of the cover layer 400 while maintaining the cover layer 400 itself, even when the outgassing of N₂ gas or the like occurs during etching of the intermediate layer 300 in the porous step S50 described later. Thus, the cover layer 400 can be prevented from being peeled off from the intermediate layer 300.

On the other hand, by setting the thickness of the cover layer 400 to 2 μm or less or 1.5 m or less, the electrolyte is allowed to stably reach the intermediate layer 300 through the dislocations D of the cover layer 400 in the porous step S50 described later. Thus, the voids can be formed stably in the intermediate layer 300.

After growing the cover layer 400, the temperature of the base substrate 100 is decreased from the growth temperature of group III nitride crystal to room temperature. Thus, a laminated body including the base substrate 100, the base layer 200, the intermediate layer 300, and the cover layer 400 is formed.

At this time, the entire laminated body is warped due to a difference in linear expansion coefficient between the base substrate 100 and the group III nitride crystal layers including the base layer 200, the intermediate layer 300, and the cover layer 400, as shown in FIG. 3B. Specifically, since the linear expansion coefficient of sapphire as the base substrate 100 is greater than that of a group III nitride, the entire laminated body is warped such that the surface of the cover layer 400 becomes convex.

The base layer formation step S20, the intermediate layer formation step S30, and the cover layer formation step S40 described above are continuously performed in the same chamber without exposing the base substrate 100 to the atmosphere. This can suppress unintentional incorporation of at least any one of oxygen (O) and silicon (Si) as an n-type impurity at the interfaces between the base layer 200 and the intermediate layer 300 and between the intermediate layer 300 and the cover layer 400. As a result, the effect on the carrier concentration in these layers can be suppressed.

### (S50: Porous Step)

After forming the cover layer 400, as shown in FIG. 4, the intermediate layer 300 is made porous through the dislocations D in the cover layer 400 by performing the electrochemical process while maintaining the surface condition of the cover layer 400.

Specifically, the electrochemical process is performed, for example, by the following procedure.

As shown in FIG. 4, first, a process tank 820, a power source 840, and a current meter 860 are prepared. The power source 840 and the current meter 860 may be incorporated into one device as a current-voltage power source.

The process tank 820 is filled with an electrolyte 810. The electrolyte 810 is a solution containing ions capable of electrochemically etching a group III nitride. Examples of the electrolyte 810 include aqueous solutions containing oxalic acid, nitric acid, hydrofluoric acid, sulfuric acid, sodium sulfate (Na₂SO₄), sodium chloride (NaCl), sodium hydroxide (NaOH), and the like. Here, the electrolyte 810 is assumed to be an oxalic acid solution.

Furthermore, each electrode for performing the electrochemical process is prepared. Specifically, in a laminated body obtained after the completion of the above cover layer formation step S40, the anode 842 is provided on the surface of the cover layer 400, and the anode 842 is connected to the power source 840. Meanwhile, a cathode 844 is prepared. The cathode 844 is connected to the power source 840. For the cathode 844, a material that is resistant to corrosion but allows current to flow easily is used. Specific examples of the material for the cathode 844 include stainless steel (SUS), platinum (Pt), gold (Au), and boron-doped diamond.

After the connection of each electrode is completed, a stacked body with the anode 842 connected thereto and the cathode 844 are immersed into the electrolyte 810 in the process tank 820. In this state, a predetermined voltage is applied between the anode 842 and the cathode 844 by the power source 840. Thus, the electrochemical process is performed. At this time, the progress of the electrochemical process is checked based on a change in the current at the current meter 860.

At this time, by performing the electrochemical process, the electrolyte containing C₂O₄²⁻ is allowed to penetrate the dislocations D in the cover layer 400, which has a relatively low carrier concentration, toward the intermediate layer 300, which has a relatively high carrier concentration. That is, the dislocation D in the cover layer 400 is used as a nano-sized path through which the electrolyte penetrates. The electrolyte having reached the intermediate layer 300 in this way selectively etches the intermediate layer 300. This creates a plurality of voids 360 near the plurality of dislocations D in the intermediate layer 300. As a result, the intermediate layer 300 can be made porous.

On the other hand, according to the following reaction equation, group III element ions (Ga³⁺) and nitrogen (N₂) gas produced when etching the intermediate layer 300 are released through the dislocations D in the cover layer 400 to the outside of the cover layer 400.

2GaN+6h⁺→2Ga³⁺+N₂,
where “h⁺” is a positive charge.

Through the above electrochemical process, each of the plurality of voids 360 in the intermediate layer 300 is formed, for example, at a position overlapping each of the plurality of dislocations D in the cover layer 400 described later. The plurality of voids 360 in the intermediate layer 300 extends, for example, from a bottom surface of the cover layer 400 toward the base substrate 100 in the thickness direction. However, the voids 360 do not need to reach the base layer 200.

Meanwhile, partition wall portions of the intermediate layer 300 other than the voids 360 connect an upper portion of the base layer 200 or a lower portion of the intermediate layer 300 with the cover layer 400. Thus, the intermediate layer 300 maintains a constant thickness even though it has the plurality of voids 360.

At this time, in the present embodiment, the length of each of the plurality of voids 360 in the intermediate layer 300 in the direction along the main surface 120 of the base substrate 100 is, for example, 30 nm or more, or may be 100 nm or more, when viewed in any cross section orthogonal to the main surface 120 of the base substrate 100. Thus, in the regrowth step S60 described later, the voids 360 in the intermediate layer 300 can be maintained. As a result, in the peeling step S70 described later, the regrowth layer 500 can be easily and stably peeled off from the base substrate 100 by using, as a boundary, at least a portion of the intermediate layer 300 maintained in a porous state.

The upper limit of the length of each of the voids 360 in the intermediate layer 300 in the direction along the main surface 120 of the base substrate 100 is not limited. However, the length of each of the voids 360 in the direction along the main surface 120 of the base substrate 100 may be 10 μm or less. Thus, by adjusting conditions for the electrochemical process appropriately in the porous step S50, the cover layer 400 can be prevented from being peeled off due to outgassing that occurs when etching the intermediate layer 300.

At this time, in the present embodiment, the depth of each of the plurality of voids 360 in the thickness direction of the intermediate layer 300 is, for example, more than 100 nm, or 500 nm or more, or may be 1 μm or more. Also, with this configuration, in the regrowth step S60 described later, the voids 360 in the intermediate layer 300 can be maintained. As a result, in the peeling step S70 described later, the regrowth layer 500 can be easily and stably peeled off from the base substrate 100.

The upper limit of the depth of each of the voids 360 is not limited. However, the depth of the void 360 may be less than or equal to the thickness of the intermediate layer 300. Thus, in the peeling step S70 described later, excessive spread of the peeling from the intermediate layer 300 to other layers can be suppressed.

Meanwhile, in the electrochemical process, almost no etching occurs on the surface of the cover layer 400 having a relatively low carrier concentration. In other words, even when the cover layer 400 has the plurality of dislocations D as described above, excessive etching does not occur on the surface of the cover layer 400 near the dislocations D. Consequently, the surface condition of the cover layer 400 can be maintained flat.

At this time, in the present embodiment, after the porous step S50, the arithmetic mean roughness (Ra) of the surface of the cover layer 400 is, for example, 1.0 nm or less, and the root mean square roughness (RMS) of the surface of the cover layer 400 is, for example, 2.0 nm or less. Alternatively, the Ra of the surface of the cover layer 400 may be, for example, 0.5 nm or less, and the RMS of the surface of the cover layer 400 may be, for example, 1.0 nm or less. Here, Ra and RMS are the values obtained when the surface of the cover layer 400 is observed with an atomic force microscope (AFM) in a field of view of 5 μm square.

By maintaining a small surface roughness of the cover layer 400 as described above, a thick regrowth layer 500 with good crystallinity can be stably grown on the cover layer 400.

The lower limits of Ra and RMS of the surface of the cover layer 400 are not limited and may be close to the Ra and RMS of the main surface 120 of the base substrate 100, respectively. Specifically, the lower limits of Ra and RMS of the surface of the cover layer 400 may be 0.1 nm and 0.2 nm, respectively.

As described above, the surface of the cover layer 400 has no etching occurring near the dislocations D. However, at any position below the surface of the cover layer 400, micro voids (not shown) that have been etched may exist in an area including the dislocation D. In this case, the micro voids are formed starting at the position below the surface of the cover layer 400 and spread out as they approach the intermediate layer 300.

Specific conditions for the electrochemical process that can implement selective etching of the intermediate layer 300 described above are, for example, as follows. A processing voltage is adjusted based on the carrier concentration of the intermediate layer 300 or the like. A processing current is adjusted based on a process area (an area of the base substrate 100). A processing time is adjusted based on the thickness of the intermediate layer 300.
Electrolyte temperature: room temperature (10° C. or higher and 30° C. or lower)
Processing voltage: 1 V or more and 200 V or less, or 10 V or more and 20 V or less
Processing current: 0.01 mA or more and 60 A or less, or 0.1 mA or more and 10 A or less
Processing time: 0.1 min or more and 180 min or less, or 1 min or more and 30 min or less

As the intermediate layer 300 is made porous through the above electrochemical process, the cover layer 400 and the laminated body including the base substrate 100 and the base layer 200 are separated, while the intermediate layer 300 made porous is interposed therebetween, as shown in FIG. 4. The presence of the voids 360 with the above-mentioned size in the intermediate layer 300 can significantly facilitate this separation.

Thus, the warpage of the cover layer 400 in the porous step S50 can be reduced to be smaller than the warpage of the cover layer 400 before the porous step S50. That is, the cover layer 400 can be brought into a condition of being nearly flat.

Meanwhile, a seed substrate 10 is brought into a condition closer to a configuration where the group III nitride crystal layer on the base substrate 100 is thin. Thus, the warpage of the base substrate 100 in the porous step S50 can be reduced to be smaller than the warpage of the base substrate 100 before the porous step S50.

After the electrochemical process, the seed substrate 10 for nitride crystal growth is removed from the electrolyte in the process tank 820. Thereafter, the seed substrate 10 for nitride crystal growth that has been removed from the process tank 820 is washed with pure water or the like and dried. Consequently, the electrolyte remaining in the voids 360 of the intermediate layer 300 is removed. In the way above, the porous step S50 is completed.

In this way, the seed substrate 10 is obtained. The seed substrate 10 is used for the regrowth step S60 and the peeling step S70 described later.

### (S60: Regrowth Step)

After the porous step S50 is completed, the regrowth layer 500 comprising group III nitride crystal is epitaxially grown on the cover layer 400. The growing method for the regrowth layer 500 uses, for example, the vapor phase growth method.

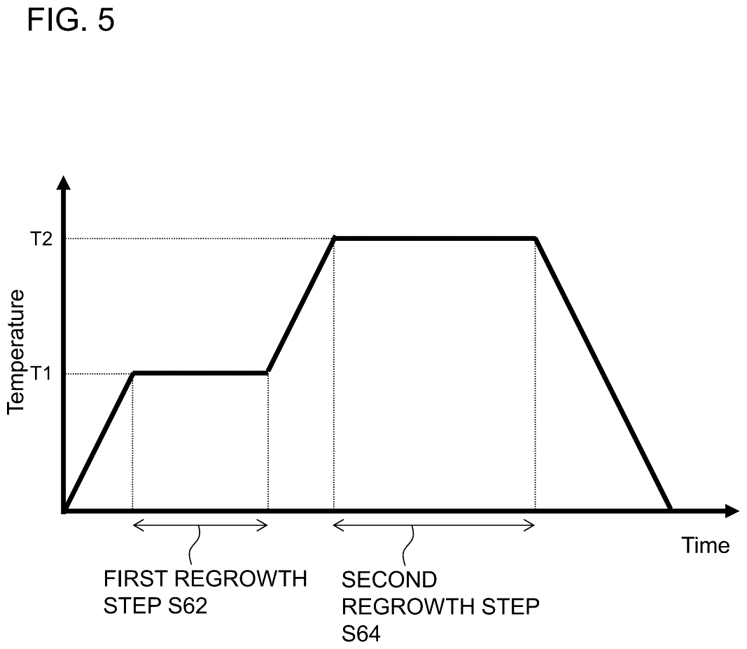

As shown in FIG. 5, in the regrowth step S60 of the present embodiment, the growth temperature is adjusted in two stages. Specifically, the regrowth step S60 has, for example, a first regrowth step S62 and a second regrowth step S64.

In the regrowth step S60, first, the temperature of the seed substrate 10 is increased from room temperature to a first growth temperature T1, as shown in FIG. 5.

### (S62: First Regrowth Step)

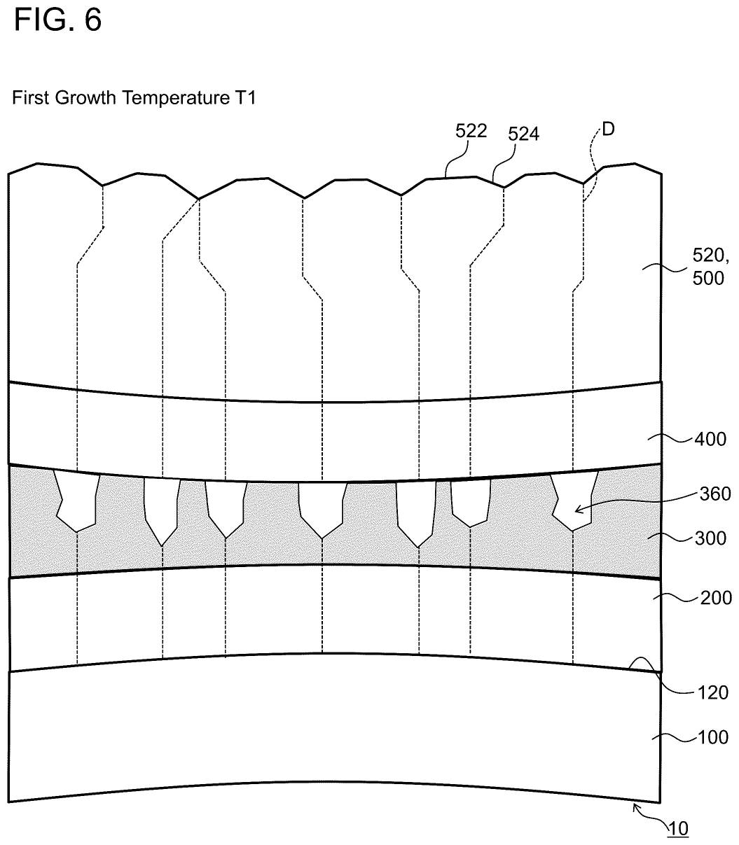

When the temperature of the seed substrate 10 reaches the first growth temperature T1, a first regrowth layer 520 is grown on the cover layer 400 at this first growth temperature T1, as shown in FIG. 6.

Specifically, a GaN layer is grown by supplying GaCl gas and NH₃ gas to the seed substrate 10 heated to the first growth temperature T1, for example, using the HVPE method. In the way above, the GaN layer is epitaxially grown on the surface of the cover layer 400 as the first regrowth layer 520. Various dopants may be added to the GaN layer as the first regrowth layer 520.

At this time, in the present embodiment, the first growth temperature T1 of the first regrowth step S62 is set lower than a second growth temperature T2 of the second regrowth step S64 as a main growth described later. That is, the first growth temperature T1 of the first regrowth step S62 is set slightly lower than the growth temperature of typical group III nitride crystal.

At this time, the base substrate 100 is elongated as the temperature increases from room temperature to the first growth temperature T1. However, since the first growth temperature T1 is lower (than the growth temperature of the base layer 200 and the like), the base substrate 100 does not become completely flat, with the main surface 120 of the base substrate 100 remaining slightly convex.

In contrast, since the linear expansion coefficient of the cover layer 400 is smaller than that of the base substrate 100, the elongation of the cover layer 400 is smaller than that of the base substrate 100. Consequently, the cover layer is warped such that the surface of the cover layer 400 is recessed. However, by making the first growth temperature T1 lower, excessive warpage of the cover layer 400 can be suppressed. Thus, the occurrence of cracks in the cover layer 400 can be suppressed. As a result, the occurrence of cracks in the regrowth layer 500 on the cover layer 400 can also be suppressed.

At this time, in the present embodiment, the first growth temperature T1 is set to 970° C. or lower, for example. This can stably suppress the occurrence of cracks in the cover layer 400 in the first regrowth step S62. As a result, the occurrence of cracks in the regrowth layer 500 on the cover layer 400 can be stably suppressed.

On the other hand, the first growth temperature T1 may be set to 800° C. or higher, for example. Thus, the group III nitride crystal can be stably grown as the first regrowth layer 520.

By adjusting the first growth temperature T1 as described above, the first regrowth layer 520 with a predetermined thickness can be grown on the cover layer 400 while suppressing the occurrence of cracks in the cover layer 400. Thus, the total thickness of the group III nitride crystal layers (cover layer 400 and first regrowth layer 520) above the intermediate layer 300 made porous can be stably thickened. As a result, in the second regrowth step S64 as the main growth described later, the group III nitride crystal layer above the intermediate layer 300 can be made less prone to cracking when the temperature is increased to the second growth temperature T2.

At this time, in the present embodiment, by starting the growth of the first regrowth layer 520 on the cover layer 400 with a flat surface, the regrowth layer 500 can be grown with a c-plane 522 (+c plane) as the growth surface without generating a crystal plane (tilted interface 524 described later) other than the c-plane 522, at an initial growth stage of the first regrowth layer 520 (at the stage where its thickness is thin). That is, the first regrowth layer 520 can be grown in a step-flow growth mode over the entire surface of the cover layer 400. Thus, the crystallinity of the first regrowth layer 520 can be improved.

Thereafter, when the first regrowth layer 520 is gradually grown, the tilted interface 524 other than the c-plane may be generated in at least a portion of the first regrowth layer 520. That is, after the first regrowth layer 520 with the predetermined thickness is grown in the step-flow growth mode, the first regrowth layer 520 may be grown three-dimensionally. Thus, at least some of the plurality of dislocations D having propagated from the cover layer 400 in the direction along the c-axis of the first regrowth layer 520 can be bent and propagate toward the direction substantially perpendicular to the respective tilted interfaces 524 at positions where the tilted interfaces 524 are exposed. This allows at least some of the plurality of dislocations D to be locally collected. By eliminating the locally collected dislocations D, the dislocation density can be reduced. As a result, the number of pits on the surface of the regrowth layer 500 can also be reduced.

At this time, in the present embodiment, the thickness of the first regrowth layer 520 is, for example, 1 μm or more, or may be 10 μm or more, or 20 μm or more. Thus, in the second regrowth step S64 as the main growth described later, the group III nitride crystal layer above the intermediate layer 300 can be stably made less prone to cracking when the temperature is increased to the second growth temperature. As a result, the occurrence of cracks and pits in a thick second regrowth layer 540 can be stably suppressed.

Meanwhile, the upper limit of the thickness of the first regrowth layer 520 is not particularly limited. However, the thickness of the first regrowth layer 520 is, for example, 300 μm or less, or may be 100 μm or less. Here, the first regrowth layer 520 grown at low temperature (grown three-dimensionally) tends to contain impurities. Thus, when the first regrowth layer 520 is grown thickly, stress may be applied between the first regrowth layer 520 and the second regrowth layer 540 described later. In contrast, by setting the thickness of the first regrowth layer 520 to 300 μm or less or 100 μm or less, excessive stress can be prevented from being applied between the first regrowth layer 520 and the second regrowth layer 540 described later due to the inclusion of impurities in the first regrowth layer 520.

When the thickness of the first regrowth layer 520 reaches a predetermined thickness, the growth of the first regrowth layer 520 is terminated by stopping the supply of GaCl gas. However, the supply of NH₃ gas is still continued.

Thereafter, the temperature of the seed substrate 10 is increased from the first growth temperature T1 to the second growth temperature T2, as shown in FIG. 5.

### (S64: Second Regrowth Step)

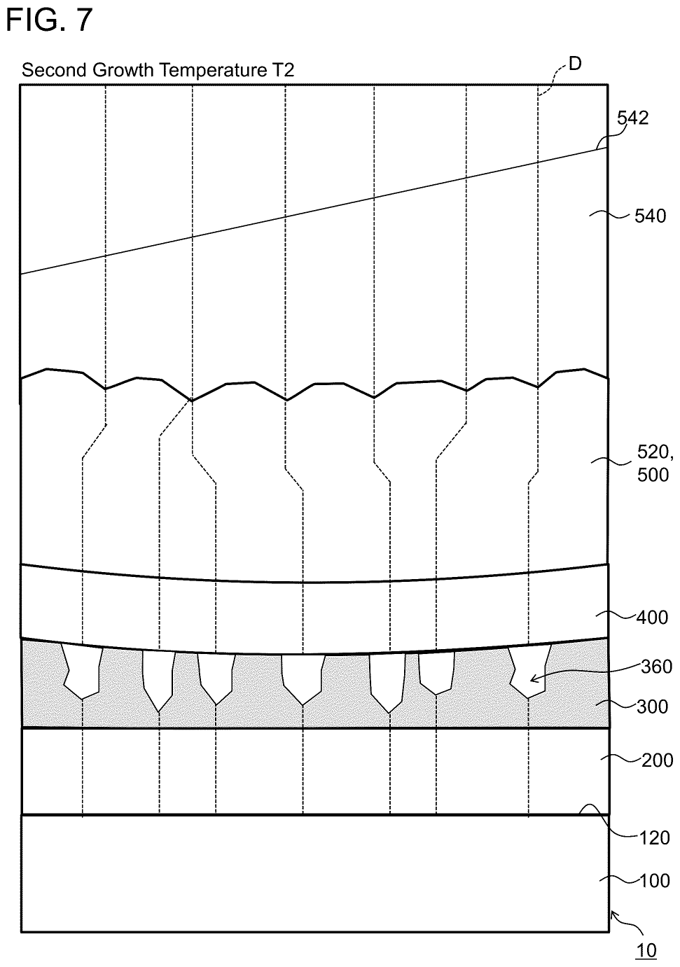

After increasing the temperature of the seed substrate 10 from the first growth temperature T1 to the second growth temperature T2, the growth of the regrowth layer 500 is resumed as the second regrowth layer 540, as shown in FIG. 7. That is, at the second growth temperature T2, the thick second regrowth layer 540 is grown as the main growth on the first regrowth layer 520.

Specifically, for example, the second regrowth step S64 is performed in the same chamber as the first regrowth step S62 without atmospheric exposure. In the second regrowth step S64, a GaN layer is epitaxially grown as the second regrowth layer 540 on the first regrowth layer 520 under the same conditions as in the first regrowth step S62, except that the growth temperature is set to the second growth temperature T2. Various dopants may be added in the GaN layer as the second regrowth layer 540.

At this time, in the present embodiment, even when the second growth temperature T2 of the second regrowth step S64 as the main growth is higher than the first growth temperature T1 of the first regrowth step S62, the group III nitride crystal layer above the intermediate layer 300 is made less prone to cracking because the total thickness of the cover layer 400 and first regrowth layer 520 as the group III nitride crystal layer above the intermediate layer 300 is set to be large, as described above. Thus, the regrowth layer 500 can be grown stably. Specifically, even when the second regrowth layer 540 is grown thickly, the occurrence of cracks and pits can be suppressed.

At this time, in the present embodiment, by setting the second growth temperature T2 of the second regrowth step S64 higher than the first growth temperature T1, the second regrowth layer 540 can be grown in the step-flow growth mode (grown two-dimensionally or grown in the lateral direction) with a c-plane 542 as the growth surface, as described above. Thus, the thick second regrowth layer 540 with good crystallinity can be grown while improving the surface flatness. Note that the c-axis, which is the normal of the c-plane 542 of the second regrowth layer 540, may be inclined at an off-angle that takes over the c-axis of the base substrate 100, which is inclined at a predetermined off-angle.

At this time, in the present embodiment, the second growth temperature T2 is, for example, 980° C. or higher, or may be 1000° C. or higher. Thus, the second regrowth layer 540 can be grown stably in the step-flow growth mode. As a result, the thick second regrowth layer 540 with good crystallinity can be grown stably while improving the flatness of the second regrowth layer 540.

Meanwhile, the second growth temperature T2 may be set to 1100° C. or lower, for example. This can suppress the roughening of the surface of the second regrowth layer 540 due to excessively high growth temperature.

At this time, in the case where the tilted interface 524 is generated in at least a portion of the first regrowth layer 520 (the first regrowth layer 520 is grown three-dimensionally) in the first regrowth step S62 of the present embodiment, the second regrowth layer 540 is grown in the horizontal direction as described above, so that a tilted interface in the second regrowth layer 540 can be gradually shrunk, that is, the c-plane 542 can be gradually enlarged. Thus, the second regrowth layer 540 with the mirror-finished surface can be grown.

At this time, in the present embodiment, the total thickness of the regrowth layer 500 (the first regrowth layer 520 and the second regrowth layer 540) is, for example, 600 μm or more, and may be 1 mm or more. The upper limit of the thickness of the regrowth layer 500 is not particularly limited. However, from the viewpoint of improving productivity, the thickness of the regrowth layer 500 may be, for example, 100 mm or less.

Here, in the growth process of the thick regrowth layer 500, the dislocations D move in a random walk manner. Thus, the dislocations D are caused to gather or to form loops during the growth of the regrowth layer 500. Such a phenomenon can reduce the number of dislocations D reaching the surface of the thick second regrowth layer 540.

Alternatively, in the first regrowth step S62 of the present embodiment, in the case where the tilted interface 524 is generated in at least a portion of the first regrowth layer 520 (the first regrowth layer 520 is grown three-dimensionally), the dislocations can be collected locally at portions where adjacent tilted interfaces gather during the process of growing the second regrowth layer 540 in the horizontal direction. Also in this case, the number of dislocations D reaching the surface of the thick second regrowth layer 540 can be reduced.

As a result, the dislocation density of the second regrowth layer 540 can be reduced. (Note that the number of dislocations in FIG. 7 is not reduced significantly for simplification of FIG. 7.)

Specifically, the dislocation density at the surface of the second regrowth layer 540 can be, for example, 3×10⁷ cm⁻² or less, 1×10⁷ cm⁻² or less, or 5×10⁶ cm⁻² or less.

### (S70: Peeling Step)

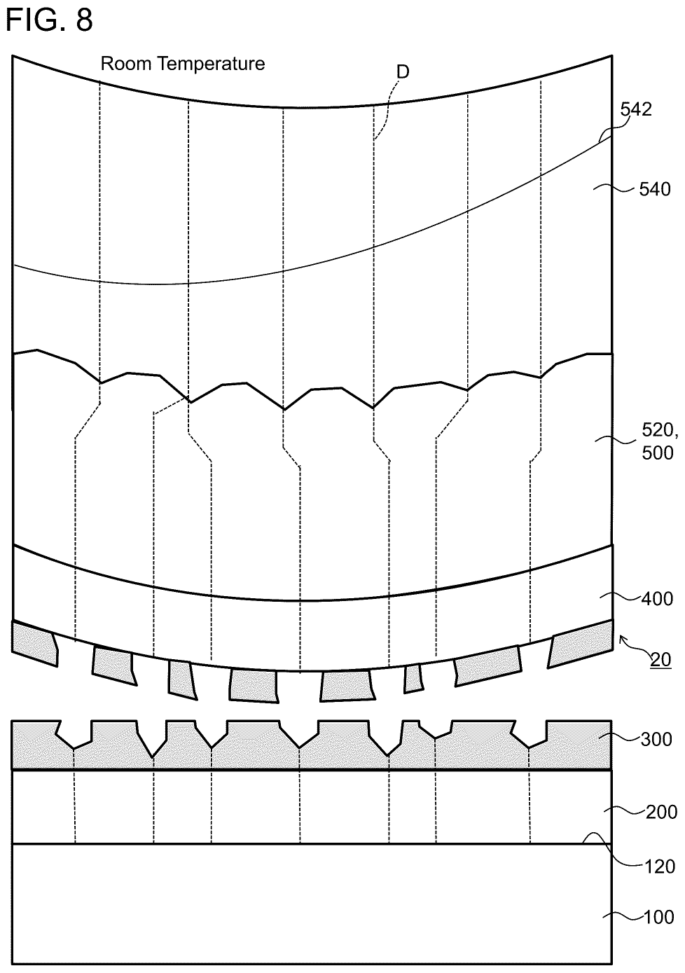

After the regrowth step S60 is completed, as shown in FIG. 8, the regrowth layer 500 is peeled off from the base substrate 100 by using at least a portion of the intermediate layer 300 made porous as the boundary.

In the present embodiment, the regrowth layer 500 is peeled off spontaneously from the base substrate 100 while decreasing the temperature after the regrowth step S60. This can eliminate the need for a special separate step of peeling. In other words, the manufacturing method can be simplified.

Here, in the regrowth step S60, tensile stress is generated in the regrowth layer 500 (in the direction along the main surface 120 of the base substrate 100). This is due to the fact that, for example, the dislocation density is reduced as the thickness of the regrowth layer 500 increases, as described above.

The tensile stress generated in the regrowth layer 500 in the direction along the main surface 120 of the base substrate 100 in this way warps the c-plane 510 of the regrowth layer 500 into a spherical shape with an upper side thereof recessed. Thus, the regrowth layer 500 is peeled off spontaneously and gradually from an outer periphery of the base substrate 100 toward a center thereof. That is, by utilizing the warpage of the c-plane 510 of the regrowth layer 500, the regrowth layer 500 can be gradually peeled off from the outer periphery of the base substrate 100 toward the center thereof. In other words, the regrowth layer 500 can be peeled off evenly in a concentric manner with respect to the center of the base substrate 100. As a result, the regrowth layer 500 with a large area can be peeled off easily and stably.

By the above peeling step S70, a peeled intermediate 20 including at least the cover layer 400 and the regrowth layer 500 is formed. Residual fragments of the intermediate layer 300 may remain on the bottom surface of the cover layer 400 of the peeled intermediate 20.

### (S80: Post-Process Step)

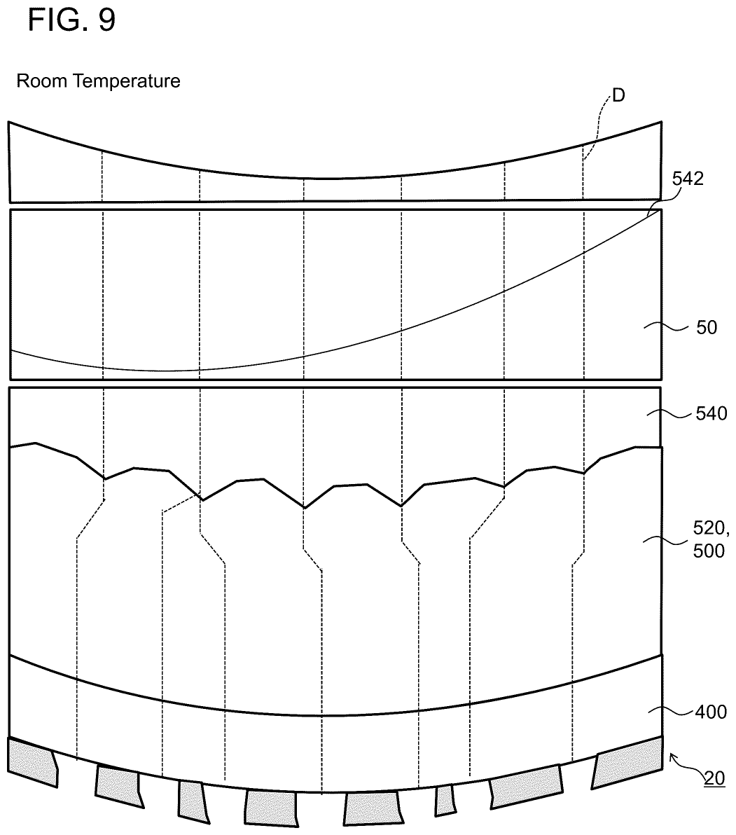

After the peeling step S70 is completed, the regrowth layer 500 is sliced by a wire saw, for example, along a cutting plane perpendicular to the normal direction at the center of the surface of the regrowth layer 500, as shown in FIG. 9. This forms a nitride crystal substrate 50 (hereinafter abbreviated as the “substrate 50”) as an as-sliced substrate.

Next, both surfaces of the substrate 50 are polished by a polishing device. Thus, the main surface of the substrate 50 becomes mirror-finished.

Through the steps described above, the substrate 50 comprising single crystal of a group III nitride of the present embodiment is obtained.

The diameter of the substrate 50 is, for example, 2 inches or more, or may be 4 inches or more. The thickness of the substrate 50 is, for example, 150 μm or more and 3 mm or less.

### (2) Summary of Present Embodiment

According to the present embodiment, one or more of the following effects can be obtained.
(a) In the porous step S50 of the present embodiment, the intermediate layer 300 is made porous through the dislocations D in the cover layer 400 by performing the electrochemical process while maintaining the surface condition of the cover layer 400. In the regrowth step S60, the regrowth layer 500 is epitaxially grown on the cover layer 400.

In the porous step S50, the electrochemical process is performed in a state where the cover layer 400 having a relatively low carrier concentration covers the intermediate layer 300 having a relatively high carrier concentration, as described above. Thus, the intermediate layer 300 can be selectively made porous through the dislocations D in the cover layer 400 while maintaining the surface condition of the cover layer 400.

By maintaining the surface condition of the cover layer 400 on the porous intermediate layer 300 to be flat, the thick regrowth layer 500 with good crystallinity can be stably grown by utilizing the cover layer 400 as a regrowth base substrate in the regrowth step S60.

Meanwhile, by covering the plurality of voids 360 in the intermediate layer 300 with the flat cover layer 400, the embedding of the voids 360 in the intermediate layer 300 during the regrowth step S60 is suppressed, allowing most of the voids 360 in the intermediate layer 300 to be maintained. Thereafter, the regrowth layer 500 can be peeled off easily and stably from the base substrate 100 by using, as the boundary, at least a portion of the intermediate layer 300 maintained in the porous state.

In the way above, according to the present embodiment, the substrate 50 comprising single crystal of a group III nitride can be easily obtained from the peeled regrowth layer 500.
(b) In the regrowth step S60 of the present embodiment, the growth temperature is adjusted in two stages. Specifically, the first growth temperature T1 of the first regrowth step S62 is set lower than the second growth temperature T2 of the second regrowth step S64 as the main growth. This can suppress the occurrence of excessive warpage of the cover layer 400 in the first regrowth step S62, thereby suppressing the occurrence of cracks in the cover layer 400.

In this way, the first regrowth layer 520 with the predetermined thickness is grown on the cover layer 400 while suppressing the occurrence of cracks in the cover layer 400. Thus, the total thickness of the group III nitride crystal layers above the intermediate layer 300 made porous can be stably thickened. As a result, when the temperature is increased to the second growth temperature T2 in the second regrowth step S64 as the main growth, the group III nitride crystal layer above the intermediate layer 300 can be made less prone to cracking.

As a result, the regrowth layer 500 can be grown stably. Specifically, even when the second regrowth layer 540 is grown thickly, the occurrence of cracks and pits can be suppressed.
(c) In the present embodiment, in the first regrowth step S62, the growth of the first regrowth layer 520 is terminated when the thickness of the first regrowth layer 520 reaches the predetermined thickness while maintaining the first growth temperature T1. In the second regrowth step S64, after increasing the growth temperature from the first growth temperature T1 to the second growth temperature T2, the growth of the regrowth layer 500 is resumed as the second regrowth layer 540.

Instead of gradually increasing the temperature in the first regrowth step S62, as described above, by differentiating between the first growth temperature T1 in the first regrowth step S62 and the second growth temperature T2 in the second regrowth step S64, it is possible to separately set the first growth temperature T1 suitable for the first regrowth layer 52 and the second growth temperature T2 suitable for the second regrowth layer 54.

Furthermore, as described above, by growing the first regrowth layer 520 with the predetermined thickness on the cover layer 400 in advance, the rate of temperature increase can be accelerated while suppressing cracks in the group III nitride crystal layer above the intermediate layer 300 when increasing the growth temperature from the first growth temperature T1 to the second growth temperature T2. As a result, the manufacturing process can be shortened.

### (3) Modification Example of One Embodiment

The above embodiment can be modified as needed, as described in the following modification examples. Hereinafter, only components that differ from those in the above embodiment will be described. Components that are substantially the same as those in the above embodiment are denoted by the same reference characters, and descriptions thereof are omitted.

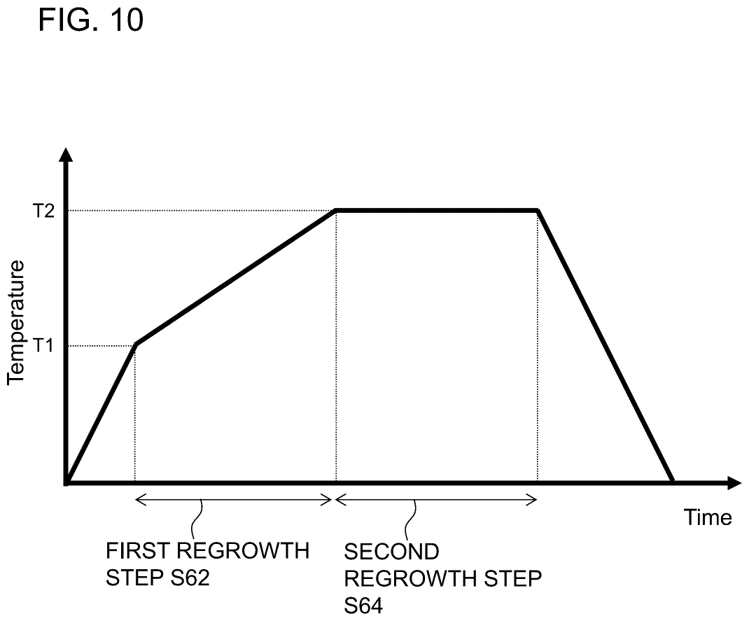

As shown in FIG. 10, in the first regrowth step S62 of Modification Example 1, the growth temperature is gradually increased from the first growth temperature T1 to the second growth temperature T2 while the first regrowth layer 520 grows.

According to Modification Example 1, the rate of temperature increase from the first growth temperature T1 to the second growth temperature T2 can be slowed down. As a result, cracks in the group III nitride crystal layer above the intermediate layer 300 that would be caused by the temperature increase step from the first growth temperature T1 to the second growth temperature T2 can be stably suppressed.

Meanwhile, according to Modified Example 1, the first regrowth step S62 serves both the growth step of the first regrowth layer 520, and the temperature increasing step from the first growth temperature T1 to the second growth temperature T2. That is, the regrowth step S60 can be shifted from the first regrowth step S62 to the second regrowth step S64 without introducing a growth stop period. Thus, in this modification example as well, the manufacturing process can be shortened.

### Other Embodiments of Present Disclosure

The embodiments of the present disclosure have been specifically described above. However, the present disclosure is not limited to the embodiments described above, and can be modified in various ways without departing from its gist.

In the embodiments described above, the base layer formation step S20 is performed, but the base layer formation step S20 may not be performed. That is, the base layer 200 may be eliminated. In the intermediate layer formation step S30, the intermediate layer 300 may be formed directly on the base substrate 100.

In the embodiments described above, an upper layer of the base layer 200, the intermediate layer 300, the cover layer 400, and the regrowth layer 500 each include GaN crystal, but the present disclosure is not limited to this case. Each layer is not limited to GaN crystal, but may include, for example, group III nitride crystal such as aluminum nitride (AlN), aluminum gallium nitride (AlGaN), indium nitride (InN), indium gallium nitride (InGaN), and aluminum indium gallium nitride (AlInGaN), that is, crystal represented by a composition formula of InₓAl_{y}Ga_{1-x-y}N (0≤x≤1, 0≤y≤1, 0≤x+y≤1).

In the embodiments described above, the Ra of the main surface 120 of the base substrate 100 is less than 0.3 nm, but the main surface 120 of the base substrate 100 may be patterned to have, for example, periodic unevenness. The base substrate 100 may be, for example, a so-called Patterned Sapphire Substrate (PSS).

In the embodiments described above, the base substrate 100 comprises a material different from a group III nitride, but the present disclosure is not limited to this case. The base substrate 100 may be a free-standing substrate comprising, for example, group III nitride crystal. In this case, due to the presence of the voids 360 in the intermediate layer 300, thermal conductivity above the intermediate layer 300 is reduced. Thus, distortion can be generated between the layer below the intermediate layer and the layer above the intermediate layer. As a result, this case may also have the same issues as in a case where the base substrate 100 is a different type of substrate. Therefore, even when using the free-standing substrate comprising group III nitride crystal, the same effect as in the above embodiment can also be obtained by applying the regrowth step S60 in two stages.

When the base substrate 100 is the free-standing substrate comprising group III nitride crystal, it may be reused after peeling off from a functional layer of a semiconductor device grown in a so-called GaN on GaN structure, for example, as in Modification Example 2 below.

In Modification Example 2, first, in the base substrate preparation step S10, a free-standing substrate comprising a group III nitride is prepared as the base substrate 100. After the base substrate preparation step S10, as in the above embodiment, the processes from the base layer formation step S20 to the porous step S50 are performed. Next, in the regrowth step S60, a functional layer is grown as the regrowth layer 500. The term “functional layer” as used herein means a layer functioning as at least a portion of the semiconductor device. In the peeling step S70, the functional layer is peeled off as the regrowth layer 500. Next, after the peeling step S70, a polishing step is performed to polish a surface of the remaining base substrate 100. After the polishing step, the base substrate 100 is reused, allowing for the repetition of a cycle from the base layer formation step S20 to the polishing step. Thus, in Modification Example 2, the free-standing substrate comprising a group III nitride as the base substrate 100 can be reused, leading to a reduction in the manufacturing costs of semiconductor devices and the like.

In the embodiments described above, the upper layer of the base layer 200, the intermediate layer 300, the cover layer 400, and the regrowth layer 500 include the same GaN crystal, but at least any one of the upper layer of the base layer 200, the intermediate layer 300, the cover layer 400, and the regrowth layer 500 may include group III nitride crystal different from those of the other layers.

In the embodiments described above, the upper layer of the base layer 200, the intermediate layer 300, the cover layer 400, and the regrowth layer 500 each contain Si as the n-type dopant, but at least any one of the upper layer of the base layer 200, the intermediate layer 300, the cover layer 400, and the regrowth layer 500 may contain, for example, oxygen (O) or germanium (Ge) as the n-type dopant.

In the embodiments described above, the above-mentioned respective vapor phase growth methods are used as growth methods for the base layer 200, the intermediate layer 300, the cover layer 400, and the regrowth layer 500, but the present disclosure is not limited to this case. A metal organic vapor phase epitaxy (MOVPE) method may be used as the growth method for at least any one of the base layer 200, the intermediate layer 300, the cover layer 400, and the regrowth layer 500. Alternatively, a growth method other than the vapor phase growth method may be used as the growth method for at least any one of the base layer 200, the intermediate layer 300, the cover layer 400, and the regrowth layer 500.

In the embodiments described above, the first regrowth layer 520 is grown three-dimensionally, but the present disclosure is not limited to this case. The growth of the first regrowth layer 520 in the step-flow growth mode may be maintained.

### EXAMPLES

The following is a description of experimental results that support the effectiveness of the above-mentioned embodiments.

### (1) Experiment 1

### (1-1) Fabrication of Seed Substrate

Three seed crystal substrates were fabricated under the same conditions according to the following procedure.

### (Base Substrate Preparation Step)

As a base substrate for obtaining a seed substrate, the following substrate was prepared.
Base substrate: Sapphire substrate
Surface orientation of main surface of base substrate: +c-plane
Diameter of base substrate: 2 inches (50.8 mm)
Thickness of base substrate: 430 μm

### (Base Layer Formation Step)

An AlN buffer layer and a GaN layer were formed on the base substrate in this order as the base layer by the HVPE method under the following conditions.
Growth temperature of base layer: 1055° C.
Thickness of AlN buffer layer and GaN layer: 100 nm and 4 m, respectively
Carrier concentration in GaN layer as base layer: about 1×10¹⁸ cm⁻³

### (Intermediate Layer Formation Step)

Next, a Si-doped GaN layer was grown as the intermediate layer on the base layer by the HVPE method under the following conditions.
Growth temperature of intermediate layer: 1055° C.
Thickness of intermediate layer: 3000 nm
Carrier concentration in intermediate layer: 6×10¹⁸ cm⁻³

### (Cover Layer Formation Step)

Next, a GaN layer was grown as the cover layer on the base layer by the HVPE method under the following conditions.
Growth temperature of cover layer: 1055° C.
Thickness of cover layer: 150 nm
Carrier concentration in cover layer: about 5×10¹⁷ cm³

### (Porous Step)

Next, the intermediate layer was made porous through dislocations in the cover layer by performing the electrochemical process under the following conditions. Consequently, the seed substrate for nitride crystal growth was obtained. Note that two seed substrates for nitride crystal growth were fabricated, one for observation and the other for regrowth.
Electrolyte temperature: room temperature (23° C.)
Processing voltage: 20 V
Processing current: 100 mA as the maximum
Processing time: 10 min
   (1-2) Heat treatment

Using the seed substrates described above, the three seed substrates were heated to 883° C., 963° C., and 1033° C., respectively, simulating the heating of the regrowth layer to the growth temperature. At this time, the heating atmosphere was an atmosphere containing N₂ gas and NH₃ gas, and the heating time was 3 minutes.

### (1-3) Evaluation

The surfaces of the three seed substrates subjected to the heat treatment described above were observed with an optical microscope.

### (1-4) Results

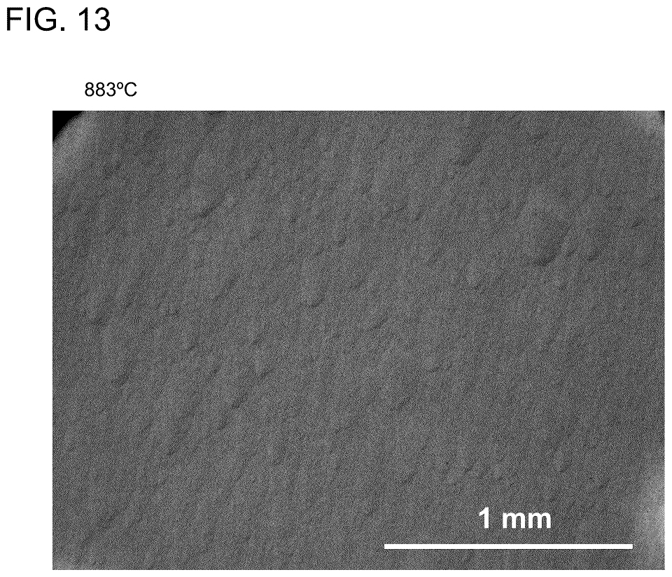

The evaluation results of Experiment 1 will be described with reference to FIGS. 13 to 15.

### (1033° C.)

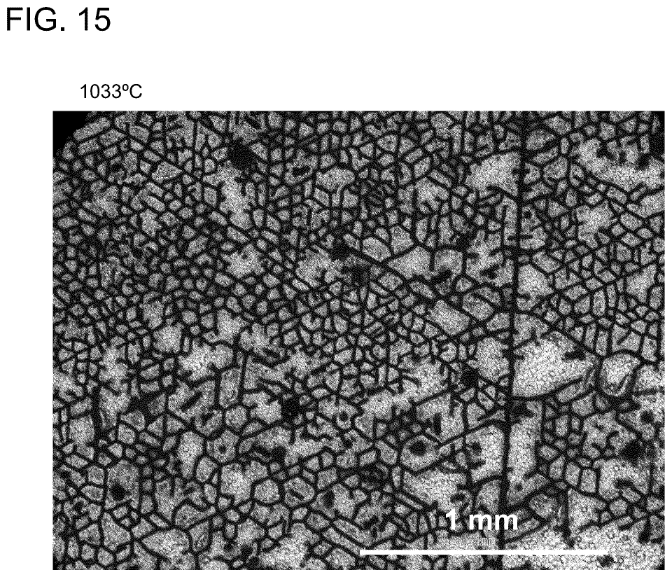

As shown in FIG. 15, the seed substrate heated to 1033° C. had many fine cracks on the surface of the cover layer. This seed substrate extended and returned to be flat as the temperature increased to 1033° C., while the cover layer on the porous intermediate layer was warped. Thus, it is considered that the heating to 1033° C. caused cracks in the cover layer.

### (963° C., 883° C.)

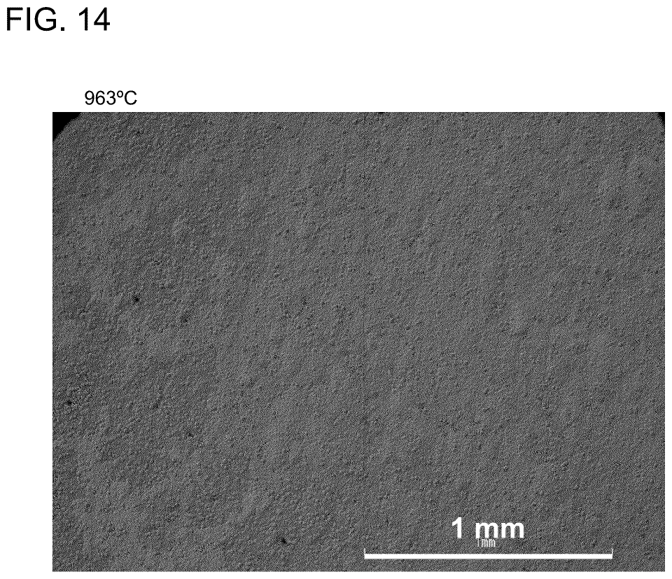

In contrast, as shown in FIGS. 13 and 14, the respective seed substrates heated to 883° C. and 963° C. showed no cracks on the surface of the cover layer, with the surface of the cover layer remaining flat. From these results, it is confirmed that when the seed substrate was heated to 970° C. or lower, the occurrence of cracks in the cover layer could be suppressed.

### (2) Experiment 2

### (2-1) Fabrication of Seed Substrate and Peeled Intermediate

In respective Samples A1, A2, B1, B2, and C1 to C4, seed substrates were fabricated under the conditions shown in Tables 1 and 2 and those described below. In Samples C1 and C3, the regrowth step was performed using the seed substrate. In Samples A1, A2, B1, B2, and C4, the regrowth step and the peeling step were performed using the seed substrate.

### <Sample A1>

In Sample A1, the seed substrate was fabricated in the same manner as in Experiment 1.

### (First Regrowth Step)

Next, a GaN layer was grown as the first regrowth layer on the cover layer by the HVPE method under the following conditions.
First growth temperature: 835° C.
Thickness of first regrowth layer: 50 μm

### (Second Regrowth Step)

Next, a GaN layer was grown as the second regrowth layer on the first regrowth layer in the same chamber as in the first regrowth step.
Second growth temperature: 1055° C.
Total thickness of regrowth layers: 1 mm

### (Peeling Step)

The regrowth layer was peeled off from the base substrate as the temperature was decreased after the regrowth step.

### <Sample A2>

In Sample A2, the seed substrate was fabricated in the same manner as in Sample A1, except that the time for the electrochemical process in the porous step was set to 20 min. Thereafter, the first regrowth step, the second regrowth step, and the peeling step were performed using the seed substrate of Sample A2 under the same conditions as in Sample A1.

### <Sample B1>

In Sample B1, the seed substrate was fabricated in the same manner as in Sample A1. Thereafter, in Sample B1, the first regrowth step, the second regrowth step, and the peeling step were performed under the same conditions as in Sample A1, except that the first growth temperature was set to 985° C.

### <Sample B2>

In Sample B2, the seed substrate was fabricated in the same manner as in Sample A1. Thereafter, in Sample B2, the first regrowth step, the second regrowth step, and the peeling step were performed under the same conditions as in Sample A1, except that the thickness of the first regrowth layer was set to 0.5 μm.

### <Sample C1>

In Sample C1, the seed substrate was fabricated in the same manner as in Sample A1, except that no cover layer was used. In Sample C1, the regrowth step was performed in the same manner as in Sample A1.

### <Sample C2>

In Sample C2, the seed substrate was fabricated in the same manner as in Sample A1, except that the thickness of the cover layer was set to 5 nm. Additionally, in Sample C2, neither the regrowth steps nor any other subsequent steps were performed.

### <Sample C3>

In Sample C3, the seed substrate was fabricated in the same manner as in Sample A1, except that the thickness of the intermediate layer was set to 50 nm. In Sample C3, the regrowth step was performed in the same manner as in Sample A1.

### <Sample C4>

In Sample C4, the seed substrate was fabricated in the same manner as in Sample A1. Thereafter, in Sample C4, the regrowth step and the peeling step were performed under the same conditions as in Sample A1, except that the first growth temperature was set to 1055° C. (that is, the first regrowth step was not performed).

### (2-2) Evaluation

Each sample was observed with the optical microscope as follows.
Cross section and surface of a laminated body after the regrowth step of each of Samples C1 and C3
Surface of a seed substrate of Sample C2
Cross section and surface of a peeled intermediate of each of Samples A1, A2, B1, B2, and C4

In the peeled intermediate of each of Samples A1, A2, B1, B2, and C4, a surface image of the regrowth layer was binarized such that pits (dark areas) and other regions (light areas) were distinguished. The ratio of the area of the pits to the unit surface area of the regrowth layer (hereinafter also referred to as a “pit area ratio of the regrowth layer”) was then determined for each sample. The unit of the pit area ratio was set to “%”. It was assumed that pits in the measurement of the pit area ratio included pits regarded as traces of cracks in the cover layer.

As a result, a case where the pit area ratio of the regrowth layer was more than 40% was designated as “C”, a case where the pit area ratio of the regrowth layer was more than 20% and less than or equal to 40% was designated as “B”, and a case where the pit area ratio of the regrowth layer was less than or equal to 20% was designated as “A”.

### (2-3) Results

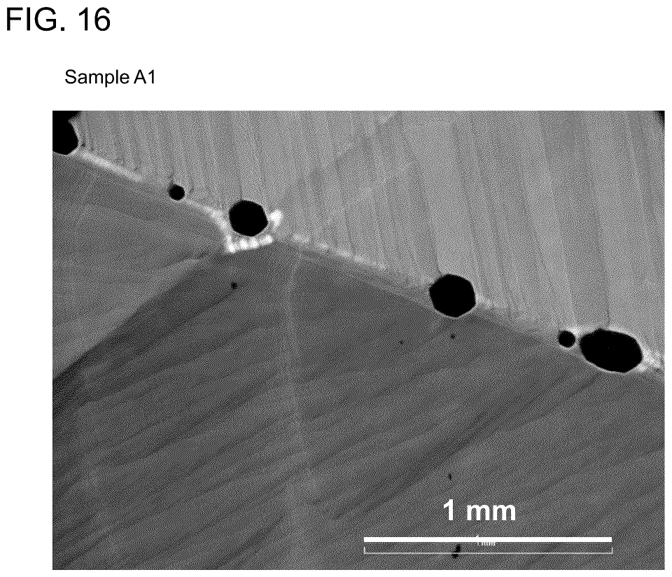

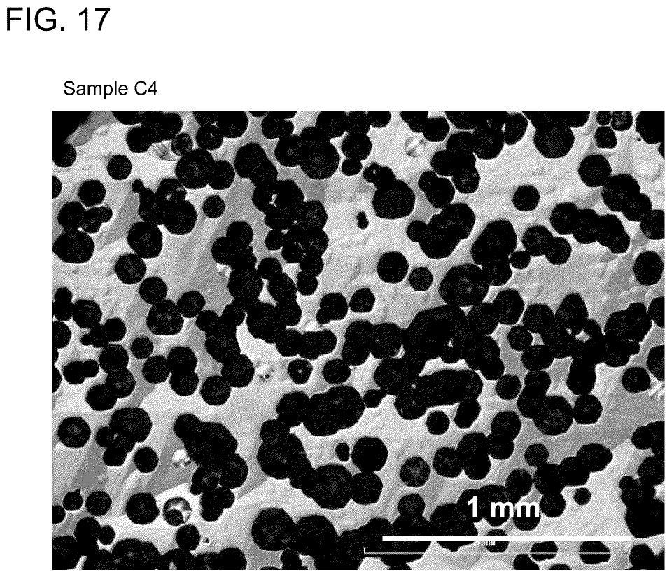

Evaluation results of Experiment 2 will be described with reference to Tables 1 and 2 and FIGS. 16 and 17.

TABLE 1

| SAMPLE | | A1 | A2 | B1 | B2 |
|---|---|---|---|---|---|
| INTERMEDIATE LAYER | THICKNESS (nm) | 3000 | 3000 | 3000 | 3000 |
| COVER LAYER | THICKNESS (nm) | 150 | 150 | 150 | 150 |
| ELECTROCHEMICAL | VOLTAGE (V) | 20 | 20 | 20 | 20 |
| PROCESS | TIME (min) | 10 | 20 | 10 | 10 |
| FIRST REGROWTH | FIRST GROWTH | 835 | 835 | 985 | 835 |
| STEP | TEMPERATURE (° C.) | | | | |
| | THICKNESS (μm) | 50 | 50 | 50 | 0.5 |
| SECOND REGROWTH | SECOND GROWTH | 1055 | 1055 | 1055 | 1055 |
| STEP | TEMPERATURE (° C.) | | | | |

| | | | | |
|---|---|---|---|---|
| TOTAL THICKNESS OF REGROWTH | 1 | 1 | 1 | 1 |
| LAYERS (mm) | | | | |
| INTERMEDIATE LAYER AFTER | VOID | VOID | VOIDS | VOIDS |
| REGROWTH STEP | MAINTAINED | MAINTAINED | PARTIALLY | PARTIALLY |
| | | | DISAPPEARED | DISAPPEARED |
| PRESENCE OR ABSENCE CRACK | ABSENCE | ABSENCE | ABSENCE | ABSENCE |
| REACHING BASE SUBSTRATE | | | | |
| PIT AREA RATIO OF REGROWTH | A | A | B | B |
| LAYER | | | | |
| PEELING STEP | PEELABLE | PEELABLE | PARTIALLY | PARTIALLY |
| | | | NON- | NON- |
| | | | PEELABLE | PEELABLE |

TABLE 2

| SAMPLE | | C1 | C2 | C3 | C4 |
|---|---|---|---|---|---|
| INTERMEDIATE LAYER | THICKNESS (nm) | 3000 | 3000 | 50 | 3000 |
| COVER LAYER | THICKNESS (nm) | ABSENCE | 5 | 150 | 150 |
| ELECTROCHEMICAL | VOLTAGE (V) | 20 | 20 | 20 | 20 |
| PROCESS | TIME (min) | 10 | 10 | 10 | 10 |
| FIRST REGROWTH | FIRST GROWTH | 835 | REGROWTH | 835 | 1055 |
| STEP | TEMPERATURE (° C.) | | STEP IS NOT | | |
| | THICKNESS (μm) | 50 | PERFORMED | 50 | 50 |
| SECOND REGROWTH | SECOND GROWTH | 1055 | BECAUSE | 1055 | 1055 |
| STEP | TEMPERATURE (° C.) | | COVER | | |

| | | | | |
|---|---|---|---|---|
| TOTAL THICKNESS OF REGROWTH | 1 | LAYER IS | 1 | 1 |
| LAYERS (mm) | | PEELED OFF | | |
| INTERMEDIATE LAYER AFTER | VOIDS | | VOIDS | VOIDS |
| REGROWTH STEP | EMBEDDED | | DISAPPEARED | PARTIALLY |
| | | | | DISAPPEARED |
| PRESENCE OR ABSENCE CRACK | PRESENCE | | PRESENCE | ABSENCE |
| REACHING BASE SUBSTRATE | | | | |
| PIT AREA RATIO OF REGROWTH | | | | C |
| LAYER | | | | |
| PEELING STEP | NON- | | NON- | PARTIALLY |
| | PEELABLE | | PEELABLE | NON- |
| | | | | PEELABLE |

### <Sample C1>

In Sample C1, the cover layer was not formed, and thus the regrowth step was performed with the porous intermediate layer exposed. Thus, the voids in the intermediate layer were embedded by the regrowth layer, resulting in the formation of a bonded region from the base substrate to the regrowth layer. As a result, after the thick regrowth layer was grown, large cracks reaching the base substrate occurred. Furthermore, the regrowth layer could not be peeled off from the base substrate.

### <Sample C2>

In Sample C2, a portion of the cover layer was peeled off after the electrochemical process. In Sample C2, since the thickness of the cover layer was less than 10 nm, it is considered that the cover layer was peeled off due to outgassing of gas generated by the electrochemical process.

### <Sample C3>

In Sample C3, the voids in the intermediate layer disappeared after the regrowth step. This is considered to be because the porous intermediate layer collapsed at the growth temperature during the regrowth. Thus, the bonded region from the base substrate to the regrowth layer was formed. As a result, after the thick regrowth layer was grown, large cracks reaching the base substrate occurred. Furthermore, the regrowth layer could not be peeled off from the base substrate.

### <Samples A1, A2, B1, B2, and C4>

In contrast, in each of Samples A1, A2, B1, B2, and C4, at least a portion of the regrowth layer could be peeled off by using at least a portion of the intermediate layer made porous as the boundary.

The results from Samples A1, A2, B1, B2, and C4 confirmed that at least a portion of the regrowth layer could be peeled off by making the intermediate layer porous, while maintaining the surface condition of the cover layer in the porous step.

<Comparison of Samples A1, A2, B1 and B2 with Sample C4>

Meanwhile, Samples A1, A2, B1 and B2 differed from Sample C4 in the following features based on the first growth temperature.

### (Sample C4)

In Sample C4, a portion of the regrowth layer could be peeled off, but some voids in the intermediate layer disappeared under the other portions of the regrowth layer. Thus, the other portion of the regrowth layer could not be peeled off from the substrate.

Furthermore, as shown in FIG. 17, Sample C4 had a number of pits on the surface of the peeled regrowth layer, resulting in a pit area ratio of C.

In Sample C4, cracks occurred in the cover layer when the temperature was increased to 1055° C., as shown in Experiment 1. In the regrowth step of Sample C4, a portion of the regrowth layer could be peeled off because the portion of the regrowth layer bonded together on the cracks in the cover layer, while maintaining the voids in the intermediate layer. However, it is considered that a number of pits were formed in the portion of the regrowth layer as traces of the cracks in the cover layer.

Meanwhile, in the regrowth step of Sample C4, voids were embedded through cracks in the cover layer in the other portion of the regrowth layer. Therefore, it is considered that the other portion of the regrowth layer could not be peeled off from the base substrate.

### (Samples A1, A2, B1 and B2)

In contrast, in Samples A1, A2, B1, and B2, at least a portion of the regrowth layer, which had occupied a larger area than in Sample C4, could be peeled off. In Samples A1, A2, B1, and B2, the pit area on the surface of the peeled regrowth layer was smaller than that in Sample C4, resulting in pit area ratios of A or B.

The results of Samples A1, A2, B1, and B2 confirmed that the occurrence of cracks and pits in the thick second regrowth layer could be suppressed by making the first growth temperature of the first regrowth step lower than the second growth temperature of the second regrowth step.

<Comparison of Samples A1 and A2 with Samples B1 and B2>

Furthermore, Samples A1 and A2 differed from Samples B1 and B2 in the following features based on the conditions for the first regrowth step.

### (Sample B1)

In Sample B1, a portion of the regrowth layer which had occupied 80% or more of the area of the regrowth layer could be peeled off, but some voids in the intermediate layer disappeared under the other portion of the regrowth layer. Thus, the other portion of the regrowth layer could not be peeled off from the base substrate.

In Sample B1, the number of pits could be reduced more than in Sample C4. However, a small number of pits were present on the surface of the peeled regrowth layer of Sample B1, resulting in a pit area ratio of B.

In Sample B1, when the temperature was increased to 985° C., fine cracks occurred in some portions of the cover layer. In Sample B1, the portions of the regrowth layer on the cracks in the cover layer were bonded together more easily than in Sample C4, so that a portion of the regrowth layer could be peeled off over a large area. However, it is considered that although the number of pits was reduced in Sample B1, a small number of pits were formed in the portion of the regrowth layer in Sample B1 as the traces of the cracks in the cover layer.

On the other hand, it is considered that in Sample B1, the other portion of the regrowth layer could not be peeled off from the base substrate due to the embedding of voids through the fine cracks in the cover layer, as in Sample C4.

### (Sample B2)

Sample B2 showed results that were substantially the same as those of Sample B1.

In Sample B2, since the thickness of the first regrowth layer was less than 1 m, fine cracks occurred in portions of the first regrowth layer when the temperature was increased to the second growth temperature. As a result, it is considered that Sample B2 could gain substantially the same results as those of Sample B1.

### (Samples A1 and A2)

In contrast, in Samples A1 and A2, the regrowth layer occupying a larger area than in Samples B1 and B2 could be peeled off. Furthermore, as shown in FIG. 16, in Samples A1 and A2, the number of pits on the surface of the peeled regrowth layer was smaller than in Samples B1 and B2, resulting in a pit area ratio of A.

The results of Samples A1 and A2 confirmed that the occurrence of cracks and pits in the thick second regrowth layer could be suppressed stably by setting the first growth temperature to 970° C. or lower and the thickness of the first regrowth layer to 1 μm or more in the first regrowth step.

### <Supplementary Descriptions>

Hereinafter, aspects of the present disclosure will be supplementarily described.

### (Supplementary Description 1)

A production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process, while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary,
(e) comprising:
(e1) growing a first regrowth layer on the cover layer at a first growth temperature; and
(e2) growing a second regrowth layer on the first regrowth layer at a second growth temperature, wherein
in (e1),
the first growth temperature is set lower than the second growth temperature.

### (Supplementary Description 2)

The production method for a nitride crystal substrate according to the supplementary description 1, wherein
in (a),
the base substrate comprising a material different from a group III nitride is prepared.

### (Supplementary Description 3)

The production method for a nitride crystal substrate according to the supplementary description 1 or 2, wherein
in (b),
the intermediate layer has a thickness of more than 100 nm.

### (Supplementary Description 4)

The production method for a nitride crystal substrate according to any one of the supplementary descriptions 1 to 3, wherein
in (c),
the cover layer has a thickness of 10 nm or more.

### (Supplementary Description 5)

The production method for a nitride crystal substrate according to any one of the supplementary descriptions 1 to 4, wherein
in (d),
warpage of the cover layer is reduced to be smaller than warpage of the cover layer before (d).

### (Supplementary Description 6)

The production method for a nitride crystal substrate according to any one of the supplementary descriptions 1 to 5, wherein
in (e1),
the first growth temperature is 970° C. or lower.

### (Supplementary Description 7)

The production method for a nitride crystal substrate according to any one of the supplementary descriptions 1 to 6, wherein
in (e1),
the first regrowth layer has a thickness of 1 μm or more.

### (Supplementary Description 8)

The production method for a nitride crystal substrate according to any one of the supplementary descriptions 1 to 7, wherein
in (e2),
the second growth temperature is 980° C. or higher.

### (Supplementary Description 9)

The production method for a nitride crystal substrate according to any one of the supplementary descriptions 1 to 8, wherein
in (e1),
a tilted interface other than (0001) is generated in at least a portion of the first regrowth layer, and
in (e2),
the tilted interface is gradually shrunk to grow the second regrowth layer with a mirror-finished surface.

### (Supplementary Description 10)

The production method for a nitride crystal substrate according to any one of the supplementary descriptions 1 to 9, wherein
in (e1),
the growth of the first regrowth layer is terminated when a thickness of the first regrowth layer reaches a predetermined thickness while maintaining the first growth temperature, and
in (e2),
after increasing a growth temperature from the first growth temperature to the second growth temperature, the growth of the regrowth layer is resumed as the second regrowth layer.

### (Supplementary Description 11)

The production method for a nitride crystal substrate according to any one of the supplementary descriptions 1 to 9, wherein
in (e1),
a growth temperature is gradually increased from the first growth temperature to the second growth temperature while the first regrowth layer grows.

### (Supplementary Description 12)

A peeled intermediate obtained by the production method for a nitride crystal substrate according to any one of the supplementary descriptions 1 to 11, comprising:
at least the cover layer and the regrowth layer.

### REFERENCE SIGNS LIST

10 Seed substrate for nitride crystal growth
20 Peeled intermediate
50 Substrate
100 Base substrate
120 Main surface
200 Base layer
300 Intermediate layer
360 Void
400 Cover layer
500 Regrowth layer
520 First regrowth layer
540 Second regrowth layer
510 c-Plane
810 Electrolyte
820 Process tank
840 Power source
842 Anode
844 Cathode
860 Current meter

What is claimed is:

1. A production method for a nitride crystal substrate, comprising:
(a) preparing a base substrate;
(b) forming an intermediate layer including n-type group III nitride crystal, above the base substrate;
(c) forming a cover layer on the intermediate layer, the cover layer including group III nitride crystal having a carrier concentration lower than a carrier concentration of the intermediate layer;
(d) making the intermediate layer porous through dislocations in the cover layer by performing an electrochemical process, while maintaining a surface condition of the cover layer;
(e) epitaxially growing a regrowth layer comprising group III nitride crystal, on the cover layer; and
(f) peeling off the regrowth layer from the base substrate by using at least a portion of the intermediate layer made porous as a boundary,
(e) comprising:
(e1) growing a first regrowth layer on the cover layer at a first growth temperature; and
(e2) growing a second regrowth layer on the first regrowth layer at a second growth temperature, wherein
in (e1),
the first growth temperature is set lower than the second growth temperature.

2. The production method for a nitride crystal substrate according to claim 1, wherein
in (b),
the intermediate layer has a thickness of more than 100 nm.

3. The production method for a nitride crystal substrate according to claim 1, wherein
in (c),
the cover layer has a thickness of 10 nm or more.

4. The production method for a nitride crystal substrate according to claim 1, wherein
in (e1),
the first growth temperature is 970° C. or lower.

5. The production method for a nitride crystal substrate according to claim 1, wherein
in (e1),
the first regrowth layer has a thickness of 1 μm or more.

6. The production method for a nitride crystal substrate according to claim 1, wherein
in (e2),
the second growth temperature is 980° C. or higher.

7. The production method for a nitride crystal substrate according to claim 1, wherein
in (e1),
a tilted interface other than (0001) is generated in at least a portion of the first regrowth layer, and
in (e2),
the tilted interface is gradually shrunk to grow the second regrowth layer with a mirror-finished surface.

8. The production method for a nitride crystal substrate according to claim 1, wherein
in (e1),
the growth of the first regrowth layer is terminated when a thickness of the first regrowth layer reaches a predetermined thickness while maintaining the first growth temperature, and
in (e2),
after increasing a growth temperature from the first growth temperature to the second growth temperature, the growth of the regrowth layer is resumed as the second regrowth layer.

9. The production method for a nitride crystal substrate according to claim 1, wherein
in (e1),
a growth temperature is gradually increased from the first growth temperature to the second growth temperature while the first regrowth layer grows.

10. A peeled intermediate obtained by the production method for a nitride crystal substrate according to claim 1, comprising:
at least the cover layer and the regrowth layer.
